(19) United States
(12) Patent Application Publication
(10) Pub. No.: US 2017/0280565 A1
(43) Pub. Date: Sep. 28, 2017

(54) JUMPERS FOR PCB DESIGN AND ASSEMBLY

(71) Applicant: BOT Home Automation, Inc., Santa Monica, CA (US)

(72) Inventor: Robert Tso, Hawthorne, CA (US)

(21) Appl. No.: 15/466,199

(22) Filed: Mar. 22, 2017

Related U.S. Application Data
(60) Provisional application No. 62/312,912, filed on Mar. 24, 2016.

(51) Int. Cl. H05K 1/18; H05K 1/11; H05K 1/02; H05K 3/34

(52) U.S. Cl. CPC H05K 1/181; H05K 3/341; H05K 3/3452; H05K 1/111; H05K 1/0286; H05K 1/0268; H05K 2201/10022; H05K 2201/10363

(57) ABSTRACT

Some embodiments provide a novel surface-mount technology (SMT) printed circuit board (PCB) assembly. The SMT PCB assembly includes at least a pair of adjacent conductive pads with a small gap between them. During the development phase of the SMT PCB assembly, the small gap between the adjacent conductive pads, as well as some of the adjacent portions of the conductive pads, are covered with solder mask. An SMT component (e.g., a zero-ohm resistor) may then be mounted to the SMT PCB assembly through the exposed portions of the conductive pads. During the production phase, however, the solder mask is revised to cover the far sides of the conductive pads, which results in the adjacent portions of the conductive pads being exposed. As such, a solder jumper can easily be created during the production phase by connecting the two conductive pads using solder paste.

### CROSS-REFERENCE TO RELATED APPLICATION

This application claims priority to provisional application Ser. No. 62/312,912, filed on Mar. 24, 2016, the entire contents of which are hereby incorporated by reference.

### TECHNICAL FIELD

The present embodiments relate to printed circuit board (PCB) assembly, in particular surface-mount technology-(SMT) based PCB assembly.

### BACKGROUND

A design for a complex electronic device often includes one or more so-called “zero-ohm” resistors during the development phase and/or the production phase. These resistors serve as jumpers, which allow the topology and/or the functionality of a circuit design to be reconfigured. They offer great utility during development, as they allow fault isolation, simply by removing a single part. For example, consider an I2C (Inter-Integrated Circuit) bus with multiple devices on the bus. If one of the devices malfunctions and holds the bus low, it is difficult to determine which device is at fault. But, if each device has a series zero-ohm resistor connecting to the bus, then fault isolation is easy. As another example, during the development phase it may be desired to measure the electrical current in a number of different circuit branches. A design engineer wishes to verify that the current draw is as expected, over temperature and operating voltage variations. One typical approach is to place low valued, current sensing resistors in each of the circuit branches of interest. Then, by measuring the voltage drop on each resistor, the currents are effectively measured by applying Ohm's law. The values of current sense resistors typically range from 0.001 ohm to 1 ohm, depending on the magnitude of current being sensed, and the amount of sense voltage desired.

Once a design has been validated, there is in many cases no need to keep the current sense resistors on the BOM (Bill of Materials) during the production phase. It is typical that relatively good accuracy (˜1%) is desired in current sense resistors used for design characterization. Low valued, accurate resistors tend to cost more than typical resistors used in a design, so in production such current sense resistors may be replaced with lower cost “zero-ohm” resistors. However, low cost zero-ohm resistors can easily exhibit larger values of resistance (e.g., 0.01 to 0.02 ohms for an 0603 case size, zero-ohm resistor) than the current sense resistors being replaced. In most applications (e.g., low voltage, high current power supply rails), it is desirable to minimize the voltage drop, and hence the electrical resistance in the power path to a value lower than what is achievable by using low cost zero-ohm resistors.

### SUMMARY

The various embodiments of the present jumpers for PCB design and assembly have several features, no single one of which is solely responsible for their desirable attributes. Without limiting the scope of the present embodiments as expressed by the claims that follow, their more prominent features now will be discussed briefly. After considering this discussion, and particularly after reading the section entitled “Detailed Description,” one will understand how the features of the present embodiments provide the advantages described herein.

The present embodiments provide a low cost, low resistance electrical jumper, and related methods, for surface-mount technology-(SMT) based PCB assembly. The present embodiments advantageously allow flexibility and utility during the development phase of a PCB-based device, while reducing parts count, assembly time, and overall cost during the mass production phase by requiring only minimal, superficial changes to the PCB design.

In certain embodiments, instead of a physical component, the present embodiments use solder to create a low cost, low resistance connection during a PCB's SMT production process. Solder is primarily and widely used to electrically connect (or mount) SMT components to a PCB assembly. The present embodiments simply modify the solder mask for a PCB between the development and production phases in order to open up areas where a jumper connection (also referred to as “solder jumper” hereinafter) is desired. The paste stencil is also modified to match the modified solder mask. During the layout design phase of the PCB, a copper etch layer (e.g., top and/or bottom copper etch) may be designed with the forethought of implementing the present solder jumpers as a reduced cost configuration option for mass production. That is, the gap between some of the adjacent conductive pads of the PCB, on which a solder jumper might be needed, is substantially reduced during the design phase of the PCB.

In a first aspect, an SMT PCB is provided, the SMT PCB comprising at least two adjacent conductive pads, wherein a first portion of each conductive pad is covered by a solder mask to expose a second different portion of the conductive pad to be used as a landing pad for an SMT component.

In an embodiment of the first aspect, the solder mask is a first solder mask, wherein the second portion of each conductive pad is subsequently covered by a second solder mask to expose the first portion of the conductive pad.

In another embodiment of the first aspect, the first solder mask is used during a development phase while the second solder mask is used during a production phase.

In another embodiment of the first aspect, the first portion of each conductive pad is adjacent an edge of the other conductive pad.

In another embodiment of the first aspect, the second portion of each conductive pad is located on a far side of the conductive pad in relation to the other conductive pad.

In another embodiment of the first aspect, the SMT component is a zero-ohm resistor.

In another embodiment of the first aspect, the first portions of the conductive pads are exposed to apply solder paste on the first portions and to create a solder jumper.

In another embodiment of the first aspect, the solder jumper replaces the SMT component.

In another embodiment of the first aspect, the SMT component is soldered to the second portions of the conductive pads to conduct design tests.

In another embodiment of the first aspect, the first portions of the conductive pads extend under a body of the SMT component.

In another embodiment of the first aspect, the adjacent conductive pads are separated by a gap having a width between 0.003″ and 0.010″.

In another embodiment of the first aspect, an edge of each conductive pad comprises a tab portion that extends toward the other conductive pad.

In another embodiment of the first aspect, the tab portions are offset from one another in a transverse direction.

In another embodiment of the first aspect, an edge of each conductive pad comprises a set of interlocking fingers extending toward the other conductive pad.

In another embodiment of the first aspect, the adjacent conductive pads are separated by a gap having an offset configuration, the offset configuration comprising a first portion that extends in a transverse direction, a second portion that extends in the transverse direction and that is offset from the first portion by an offset distance, and a third portion that extends perpendicularly to the first and second portions and connects adjacent ends of the first and second portions.

Another embodiment of the first aspect further comprises a solder jumper bridging the gap between the first and second conductive pads.

In a second aspect, a method for implementing a solder jumper on a surface-mount technology (SMT) printed circuit board (PCB) is provided, the method comprising receiving a PCB having a plurality of conductive pads for mounting a plurality of SMT components to the PCB; applying a first solder mask on the PCB such that a first portion of each conductive pad in a pair of adjacent conductive pads is covered by the first solder mask to expose a second portion of each conductive pad in the pair of adjacent conductive pads; mounting an SMT component to the PCB through the pair of adjacent conductive pads in order to perform design tests; and applying a second solder mask on the PCB after removing the SMT component, wherein the second solder mask covers the second portion of each conductive pad in the pair of adjacent conductive pads to expose the first portion of each conductive pad in the pair of adjacent conductive pads.

An embodiment of the second aspect further comprises implementing a solder jumper by connecting the first exposed portions of the pair of adjacent conductive pads using solder.

In another embodiment of the second aspect, the first portion of each conductive pad in the pair of adjacent conductive pads is adjacent an edge of the other conductive pad in the pair of adjacent conductive pads.

In another embodiment of the second aspect, the second portion of each conductive pad in the pair of adjacent conductive pads is located on a far side of each conductive pad in relation to the other conductive pad in the pair of adjacent conductive pads.

In another embodiment of the second aspect, the SMT component is a zero-ohm resistor, wherein the solder jumper subsequently replaces the zero-ohm resistor.

In another embodiment of the second aspect, an edge of each conductive pad in the pair of conductive pads comprises a tab portion that extends toward the other conductive pad in the pair of conductive pads.

In another embodiment of the second aspect, an edge of each conductive pad in the pair of conductive pads comprises a set of interlocking fingers extending toward the other conductive pad in the pair of conductive pads.

In a third aspect, a surface-mount technology (SMT) printed circuit board (PCB) assembly is provided, the SMT PCB assembly comprising at least one solder jumper comprising a pair of conductive pads and solder connecting the conductive pads, wherein a portion of each conductive pad is covered by solder mask.

In an embodiment of the third aspect, the solder jumper replaces a resistor that was mounted to the SMT PCB assembly.

In another embodiment of the third aspect, the resistor comprises a zero-ohm resistor.

In another embodiment of the third aspect, the portion of each conductive pad that is covered by the solder mask was previously exposed for performing design tests.

In another embodiment of the third aspect, the solder mask is a first solder mask, wherein the currently exposed portion of each conductive pad was previously covered by a second solder mask for performing the design tests.

In another embodiment of the third aspect, an edge of each conductive pad comprises a tab portion that extends toward the other conductive pad.

In another embodiment of the third aspect, the tab portions are offset from one another in a transverse direction.

In another embodiment of the third aspect, an edge of each conductive pad comprises a set of interlocking fingers extending toward the other conductive pad.

In another embodiment of the third aspect, the conductive pads are separated by a gap having an offset configuration, the offset configuration comprising a first portion that extends in a transverse direction, a second portion that extends in the transverse direction and that is offset from the first portion by an offset distance, and a third portion that extends perpendicularly to the first and second portions and connects adjacent ends of the first and second portions.

In another embodiment of the third aspect, the conductive pads are separated by a gap having a width between 0.003″ and 0.010″.

### BRIEF DESCRIPTION OF THE DRAWINGS

The various embodiments of the present jumpers for PCB design and assembly now will be discussed in detail with an emphasis on highlighting the advantageous features. These embodiments depict the novel and non-obvious jumpers for PCB design and assembly shown in the accompanying drawings, which are for illustrative purposes only. These drawings include the following figures, in which like numerals indicate like parts:

FIG. 1 is a schematic diagram illustrating a prior art resistor land pattern of a kind typically used in PCB physical design;

FIG. 2 is a schematic diagram illustrating the prior art resistor land pattern of FIG. 1 with a resistor attached after a PCB SMT assembly process;

FIG. 3 is a flowchart illustrating a process for implementing a solder jumper on an SMT PCB according to the present embodiments;

FIG. 4 is a schematic diagram illustrating one configuration of an SMT component land pattern for a development phase of an SMT PCB according to the present embodiments;

FIG. 5 is a schematic diagram illustrating the resistor land pattern of FIG. 4 with a resistor attached during a development phase of a PCB SMT process according to the present embodiments;

FIG. 6 is a schematic diagram illustrating one configuration of an SMT component land pattern for a production phase of an SMT PCB according to the present embodiments;

FIG. 7 is a schematic diagram illustrating the component land pattern of FIG. 6 with a jumper implemented during a production phase of an SMT PCB process according to the present embodiments;

FIG. 8 is a schematic diagram illustrating another configuration of an SMT component land pattern for a production phase of a PCB SMT process according to the present embodiments; and

FIG. 9 is schematic diagram illustrating another configuration of an SMT component land pattern for a production phase of a PCB SMT process according to the present embodiments.

### DETAILED DESCRIPTION

The following detailed description describes the present embodiments with reference to the drawings. In the drawings, reference numbers label elements of the present embodiments. These reference numbers are reproduced below in connection with the discussion of the corresponding drawing features.

Some of the present embodiments provide a novel surface-mount technology (SMT) printed circuit board (PCB) assembly. The SMT PCB assembly of some embodiments includes at least a pair of adjacent conductive pads with a small gap between them. During the development phase of the SMT PCB assembly, the small gap between the adjacent conductive pads, as well as some of the adjacent portions of the conductive pads, are covered with solder mask. An SMT component (e.g., a zero-ohm resistor) may then be mounted to the SMT PCB assembly through the exposed portions of the conductive pads. During the production phase, however, the solder mask is revised to cover the far sides of the conductive pads, which results in the adjacent portions of the conductive pads being exposed. As such, a solder jumper can easily be created during the production phase by connecting the two conductive pads using solder paste, which connects the two pads during solder reflow.

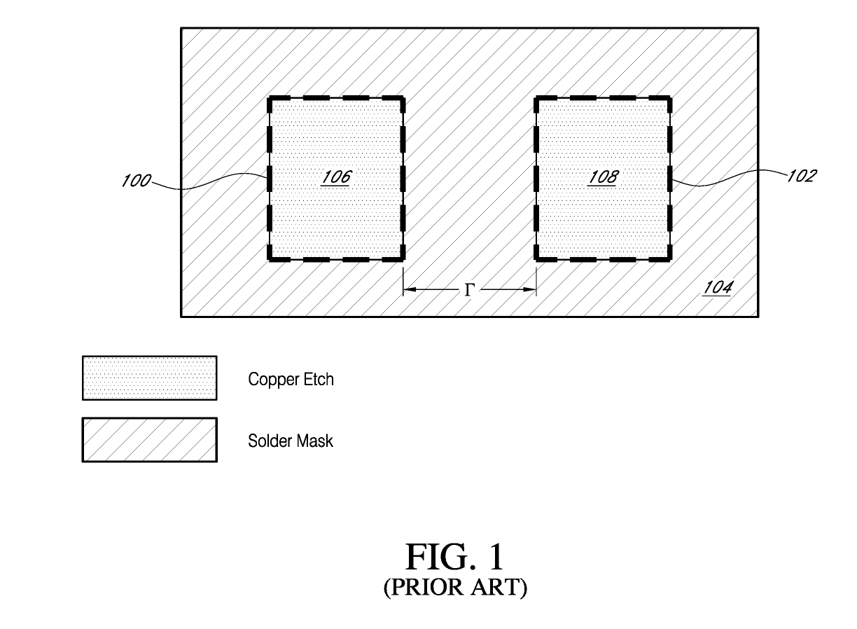

FIG. 1 illustrates a prior art resistor land pattern of a kind typically used in printed circuit board (PCB) physical design. First and second openings 100, 102 in a physical solder mask 104 expose first and second spaced conductive pads 106, 108. The physical solder mask 104 is normally a nonconductive layer used to protect and insulate the entire surface(s) of a PCB (e.g., top and bottom surfaces of a double-sided PCB). The solder mask layer is a “negative” mask layer. It defines those areas where solder mask material is not desired, e.g. over all device pads, any test points, or any other area requiring soldering or electrical and/or thermal contact. All other areas are covered by physical solder mask as the last, or nearly the last, process step of PCB fabrication.

The solder paste layer defines all areas where physical solder paste will be deposited. A solder paste mask is a CAD (computer-aided design) output (e.g. Gerber file) used as input to make a solder paste stencil. The stencil is a physical tooling used to silkscreen physical solder paste onto the physical PCB. The design of the stencil controls the location and volume of physical solder paste deposited onto the PCB. Physical solder paste comprises a mixture of microscopic solder balls suspended in a liquid flux. The flux holds the solder balls together and improves the wetting and adhesion of solder to SMT component terminals and PCB conductive (or landing) pads during the SMT oven reflow process. The physical solder mask typically has a thickness of about 0.001″, and the openings act as containers for the physical solder paste.

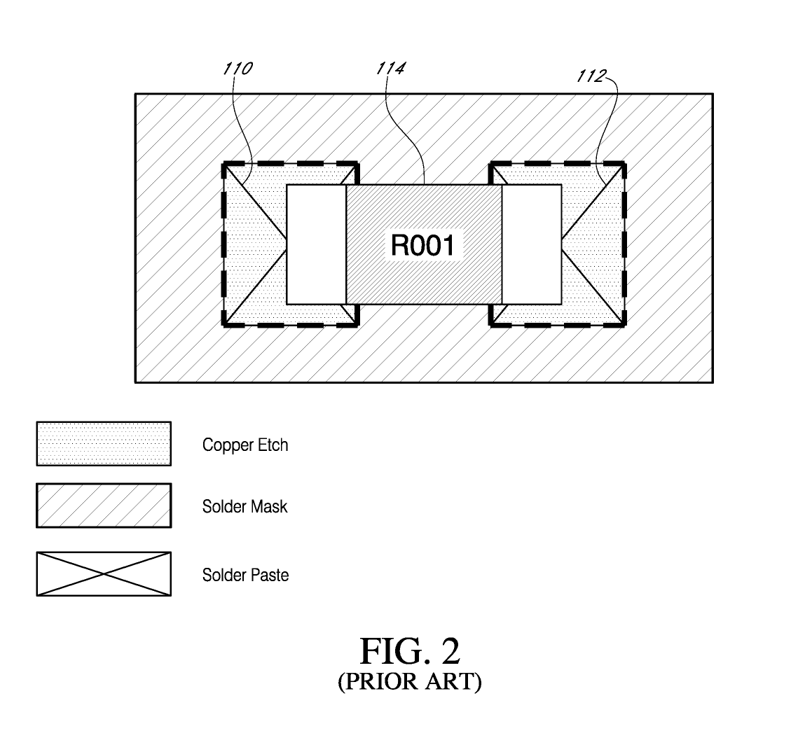

With continued reference to FIG. 1, a gap F, covered by the physical solder mask 104, separates and electrically isolates the first and second conductive pads 106, 108 from one another. A width of the gap Γ is typically in the range from 0.020″ to 0.079″ for resistor case sizes ranging from 0402 to 1206, respectively. With reference to FIG. 2, first and second portions of physical solder paste 110, 112 are applied to the first and second conductive pads 106, 108, respectively, and a resistor 114 is placed as shown to electrically connect the first and second conductive pads 106, 108 to the two terminals of the resistor 114. That is, FIG. 2 shows the terminals of the resistor 114 being placed on the landing pads 106, 108 of the PCB, which are covered by the solder paste 110, 112, respectively. After a reflow process and melting of the solder, the resistor 114 is permanently mounted to the PCB.

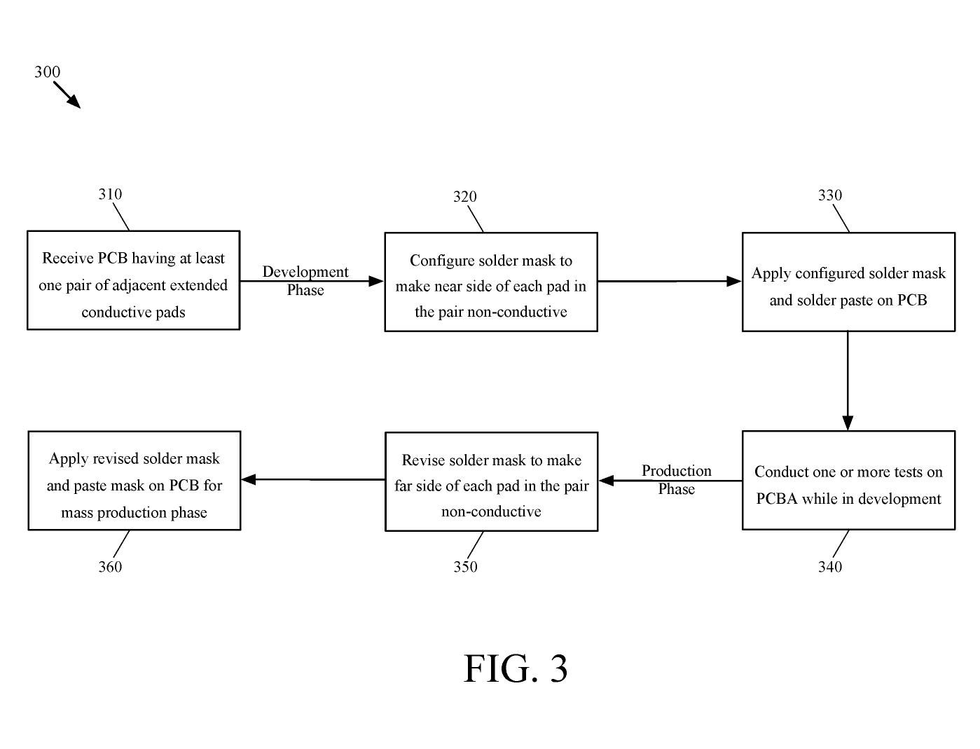

FIG. 3 conceptually illustrates a process 300 for implementing a solder jumper on an SMT PCB according to the present embodiments. At block 310, a PCB that has at least one pair of adjacent extended conductive pads is received. The conductive pads have a gap between them that is narrower than a typical gap between a pair of landing pads in prior art processes. For example, if a typical gap between the landing pads of a resistor is between 0.020″-0.079″, the width of a gap between the landing pads of some of the present embodiments may be in the range of 0.003″ to 0.005″. During the development phase of the PCB, as shown in block 320, a solder mask is configured such that the near sides of the landing pads become non-conductive. When the configured solder mask is applied to the PCB (at block 330), not only is the gap between the landing pads covered with the solder mask, but also a portion of each landing pad that is adjacent to the gap is also covered with the physical solder mask.

At block 340, one or more development phase tests may be conducted on the PCB. For instance, each device on an I2C bus may be connected to a zero-ohm resistor in series. Each of the zero-ohm resistors may be mounted to the PCB through a pair of landing pads created by the solder mask of block 320. When one of the devices malfunctions and holds the bus low, the fault can be easily identified by simply connecting and removing the zero-ohm resistors. With continued reference to FIG. 3, when the design tests of the development phase are completed, the zero-ohm resistor landing pads may be replaced with solder jumpers of the present embodiments for the production phase.

As such, at block 350, the solder mask is revised to expose the portions of the conductive pads that were previously covered by solder mask, and at the same time, to cover the far sides of conductive pads. As a result, when the revised solder mask is applied on the PCB (in block 360) for the production phase, the small area that covers the gap between the landing pads, as well as the exposed portions of the landing pads, can be easily turned to a solder jumper by applying solder paste on the small area.

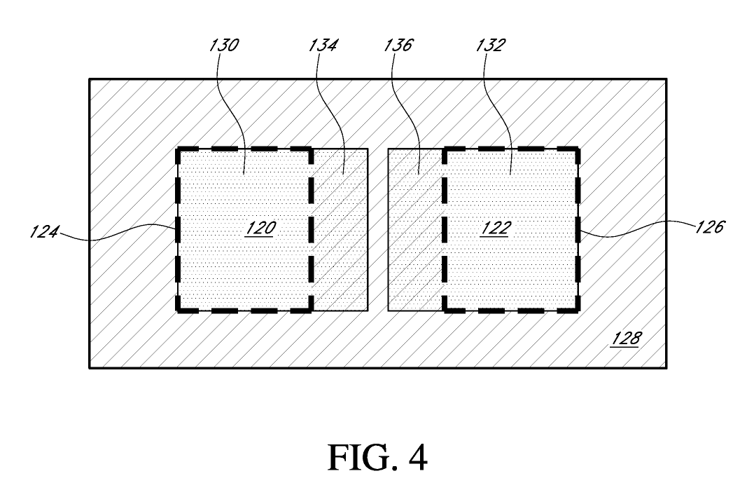

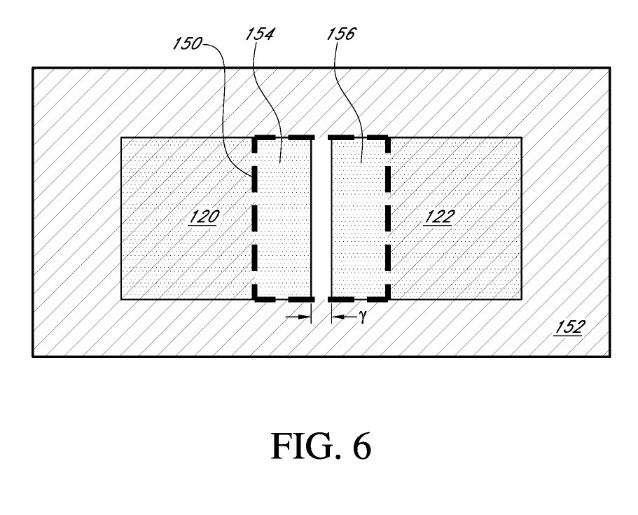

FIG. 4 illustrates a configuration for an SMT component land pattern (e.g., an SMT resistor land pattern) according to the present embodiments. The conductive pads 120, 122 shown in FIG. 4 are configured for a development phase PCB land pattern (as shown in FIG. 6, the same land pattern is revised (or reconfigured) by applying a revised solder mask for a production phase of the PCB). With reference to FIG. 4, the PCB includes first and second conductive pads 120, 122. The conductive pads 120, 122 may comprise copper, for example, or a copper alloy, or any other electrically conductive material. First and second openings 124, 126 in a physical solder mask 128 create first and second exposed portions 130, 132, respectively, of the first and second conductive pads 120, 122. However, the physical solder mask 128 covers first and second covered portions 134, 136, respectively, of the first and second conductive pads 120, 122.

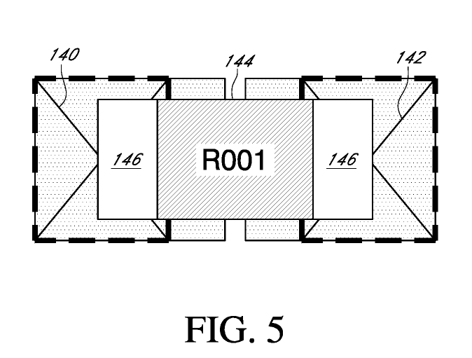

With reference to FIG. 5, first and second portions of physical solder paste 140, 142 are applied to the first and second exposed portions 130, 132, respectively, of the first and second conductive pads 120, 122. A resistor 144 is then placed on the conductive pads 120, 122 (e.g., during the development phase) to connect these conductive pads to first and second terminals 146 of the resistor 144. In some embodiments, the connection is established when the printed circuit assembly (PCA) has completed its heating and cooling profile through the SMT oven reflow process.

With reference to FIG. 6, during a production phase of the PCB, a physical solder mask having a different configuration (compared to FIG. 4) is used to create a production version of the PCB. In the configuration of FIG. 6, an opening 150 in the physical solder mask 152 is positioned over portions of both the first and second conductive pads 120, 122. Thus, first and second exposed portions 154, 156 of the first and second conductive pads 120, 122, respectively, are adjacent one another with no intervening portion of the physical solder mask separating the first and second exposed portions 154, 156 (again, in contrast to the configuration of FIG. 4).

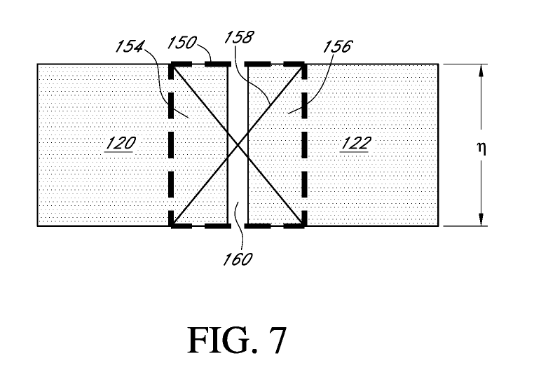

With reference to FIG. 7, physical solder paste 158 is applied in the area of the opening 150 in the physical solder mask 152 and covers the first and second exposed portions 154, 156, respectively, of the first and second conductive pads 120, 122. After SMT reflow, the physical solder paste 158 in the opening 150 forms a solder jumper 160 that electrically connects the first and second conductive pads 120, 122 to one another.

With reference back to FIG. 6, a gap γ separates the first and second conductive pads 120, 122 from one another. A width of the gap γ is preferably in the range from 0.003″ to 0.010″, and more preferably in the range from 0.003″ to 0.005″. The width of the gap γ is preferably less than the width of a typical gap Γ (0.020″ to 0.079″, as discussed above with respect to FIG. 1) between conductive pads. The narrower width creates advantages. For example, the narrower gap γ makes it easier for the jumper 160 to physically bridge the gap γ and short out both pads 120, 122. During the SMT process, the PCB assembly, including all deposited solder paste, is heated to achieve a specified temperature-versus-time profile. This profile is designed to ensure that the solder balls within the solder paste melt and coalesce by way of natural surface tension while in a liquid state.

If the width of the gap γ is too large (e.g. the width of the gap Γ in standard resistor land patterns) the solder may not bridge predictably due to surface tension in the liquid solder tending to form curved surfaces, particularly for larger resistor land patterns, e.g. 0603, 0805, 1206, 2512, etc. Another advantage of the narrower gap γ is that a small gap allows less solder material to be used to form the jumper 160, which reduces production costs. Still another advantage of the narrower gap γ is that the electrical resistance of the jumper 160 is reduced compared to a solder jumper made using a larger gap. A minimized electrical resistance is often desired in power paths to reduce excess voltage drop and power dissipation in said paths.

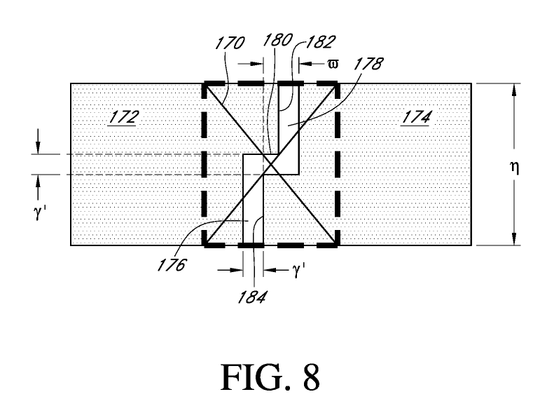

FIG. 8 illustrates another configuration for an SMT component land pattern such as a resistor land pattern according to the present embodiments. The resistor land pattern of FIG. 8 illustrates a production phase PCB land pattern, with a solder jumper 170 bridging the gap γ′ between the first and second conductive pads 172, 174. In contrast to the gap γ of FIG. 6, which forms a straight-line separating the first and second conductive pads 120, 122, the gap γ′ of FIG. 8 has an offset configuration, including a first portion 176 that extends in a transverse direction, a second portion 178 that extends in the transverse direction and that is offset from the first portion 176 by an offset distance w, and a third portion 180 that extends perpendicularly to the first and second portions 176, 178 and connects adjacent ends of the first and second portions 176, 178. The offset configuration of the gap γ′ results from the shapes of the first and second conductive pads 172, 174, each of which includes a tab portion 182, 184 extending outward by the offset distance ω from an edge that lies closest to the other pad, where the tab portions 182, 184 are offset from one another in the transverse direction.

With further reference to FIG. 8, a width of the gap γ′ (as well as the transverse spacing γ′ between the tab portions) is preferably in the range from 0.003″ to 0.010″, and more preferably in the range from 0.003″ to 0.005″. The offset shape of the gap γ′ advantageously increases a contact length of the first and second conductive pads 172, 174 with the solder jumper 170. This advantage results from the increased perimeter length of each of the first and second conductive pads 172, 174 in the area underlying the solder jumper 170.

With reference back to FIG. 7, the perimeter length of each of the first and second conductive pads 120, 122 along the edge underlying the solder jumper 160 is equal to the height η of each pad 120, 122. By contrast, with reference to FIG. 8, the perimeter length L_{P} of each of the first and second conductive pads 172, 174 along the edge underlying the solder jumper 170 is equal to the height η of each pad plus the offset distance ω (L_{P}=η+ω). The increased contact length of the first and second conductive pads 172, 174 with the solder jumper 170 advantageously reduces the electrical resistance of the solder jumper 170.

The electrical resistivity of typical copper pads is about 1.7e-08 ohm-m at 20° C., while the electrical resistivity of typical RoHS (Restriction of Hazardous Substances) solder (Sn-2.5Ag-0.8Cu-0.5Sb) is about a factor of 7× higher at 1.21e-07 ohm-m. Therefore, the electric vector field in the cross section of the solder jumper 170 will show a high concentration of current flow at or near the gap γ′, and diminishing current flow in a direction away from the conductive pads 172, 174 upward into the bulk of the solder jumper 170. Therefore, increasing the contact length of the first and second conductive pads 172, 174 with the solder jumper 170 advantageously increases the size of the region where there is a high concentration of current flow, thereby reducing the electrical resistance of the solder jumper 170.

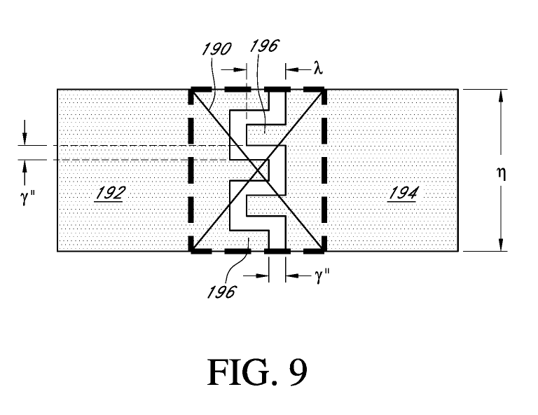

FIG. 9 illustrates another configuration for an SMT component land pattern such as a resistor land pattern according to the present embodiments. The resistor land pattern of FIG. 9 illustrates a production phase PCB land pattern, with a solder jumper 190 bridging the gap γ ″ between the first and second conductive pads 192, 194. In contrast to the gap γ of FIG. 6, which forms a straight-line separating the first and second conductive pads 120, 122, the gap γ″ of FIG. 9 has a serpentine configuration. The serpentine configuration of the gap γ ″ results from the shapes of the first and second conductive pads 192, 194, each of which includes interlocking fingers 196 extending outward by a finger length λ from an edge that lies closest to the other pad, where the interlocking fingers 196 are offset from one another in the transverse direction.

With further reference to FIG. 9, a width of the gap γ ″ (as well as the transverse spacing γ″ between adjacent ones of the interlocking fingers) is preferably in the range from 0.003″ to 0.010″, and more preferably in the range from 0.003″ to 0.005″. The serpentine shape of the gap γ ″ advantageously increases a contact length of the first and second conductive pads 192, 194 with the solder jumper 190. As described above with reference to FIG. 8, this advantage results from the increased peripheral contact area of each of the first and second conductive pads 192, 194 in the area underlying the solder jumper 190. With reference back to FIG. 7, the peripheral contact area of each of the first and second conductive pads 120, 122 along the edge underlying the solder jumper 160 is equal to the height η of each pad 120, 122.

By contrast, with reference to FIG. 9, the perimeter length L_{P} of each of the first and second conductive pads 192, 194 along the edge underlying the solder jumper 190 is equal to the height η of each pad plus the finger length λ multiplied by twice the number N of fingers 196 (L_{P}=η+2Nλ). However, if a conductive pad has fingers at both transverse ends of the gap, as does the first conductive pad 192 in FIG. 9, those fingers are counted as one finger in the foregoing formula (because each of these fingers has only one side edge located within the gap). The increased contact length of the first and second conductive pads 192, 194 with the solder jumper 190 advantageously reduces the electrical resistance of the solder jumper 190, as described above with reference to the embodiment of FIG. 8.

The present embodiments provide a low cost, low resistance electrical jumper, and related methods, for surface-mount technology-(SMT) based PCB assembly. The present embodiments advantageously allow flexibility and utility during the development phase of a PCB-based device, while reducing parts count, assembly time, possible schedule delays due to parts shortages or unavailability, and overall cost during the mass production phase by requiring only minimal, superficial changes to the PCB design. For example, the present embodiments may be implemented with only small changes to the solder mask layer. No changes to the copper etching pattern are required, although a different stencil may be used to implement the low cost jumper. But stencils are implemented as silkscreens, and are generally considered expendable manufacturing tooling that must be replaced periodically due to wear.

While the present embodiments are applicable to PCB production processes for all types of electronic devices, the present embodiments may be particularly useful in connection with audio/video (A/V) recording and communication devices (e.g., doorbells, security cameras, etc.). Examples of A/V recording and communication devices are described in the following US patent applications, each of which is incorporated herein by reference in its entirety as if fully set forth: U.S. application Ser. No. 14/334,922 (Publication No. 2015/0022618), and U.S. application Ser. No. 14/499,828 (Publication No. 2015/0022620).

The above description presents the best mode contemplated for carrying out the present embodiments, and of the manner and process of practicing them, in such full, clear, concise, and exact terms as to enable any person skilled in the art to which they pertain to practice these embodiments. The present embodiments are, however, susceptible to modifications and alternate constructions from those discussed above that are fully equivalent. Consequently, the present invention is not limited to the particular embodiments disclosed. On the contrary, the present invention covers all modifications and alternate constructions coming within the spirit and scope of the present disclosure. For example, the steps in the processes described herein need not be performed in the same order as they have been presented, and may be performed in any order(s). Further, steps that have been presented as being performed separately may in alternative embodiments be performed concurrently. Likewise, steps that have been presented as being performed concurrently may in alternative embodiments be performed separately.

What is claimed is:

1. A surface-mount technology (SMT) printed circuit board (PCB) comprising:
at least two adjacent conductive pads, wherein a first portion of each conductive pad is covered by a solder mask to expose a second different portion of the conductive pad to be used as a landing pad for an SMT component.

2. The SMT PCB of claim 1, wherein the solder mask is a first solder mask, wherein the second portion of each conductive pad is subsequently covered by a second solder mask to expose the first portion of the conductive pad.

3. The SMT PCB of claim 2, wherein the first solder mask is used during a development phase while the second solder mask is used during a production phase.

4. The SMT PCB of claim 1, wherein the first portion of each conductive pad is adjacent an edge of the other conductive pad.

5. The SMT PCB of claim 1, wherein the second portion of each conductive pad is located on a far side of the conductive pad in relation to the other conductive pad.

6. The SMT PCB of claim 1, wherein the SMT component is a zero-ohm resistor.

7. The SMT PCB of claim 1, wherein the first portions of the conductive pads are exposed to apply solder paste on the first portions and to create a solder jumper.

8. The SMT PCB of claim 7, wherein the solder jumper replaces the SMT component.

9. The SMT PCB of claim 18, wherein the SMT component is soldered to the second portions of the conductive pads to conduct design tests.

10. The SMT PCB of claim 19, wherein the first portions of the conductive pads extend under a body of the SMT component.

11. The SMT PCB of claim 1, wherein the adjacent conductive pads are separated by a gap having a width between 0.003″ and 0.010″.

12. The SMT PCB of claim 1, wherein an edge of each conductive pad comprises a tab portion that extends toward the other conductive pad.

13. The SMT PCB of claim 12, wherein the tab portions are offset from one another in a transverse direction.

14. The SMT PCB of claim 1, wherein an edge of each conductive pad comprises a set of interlocking fingers extending toward the other conductive pad.

15. The SMT PCB of claim 1, wherein the adjacent conductive pads are separated by a gap having an offset configuration, the offset configuration comprising a first portion that extends in a transverse direction, a second portion that extends in the transverse direction and that is offset from the first portion by an offset distance, and a third portion that extends perpendicularly to the first and second portions and connects adjacent ends of the first and second portions.

16. The SMT PCB of claim 15, further comprising a solder jumper bridging the gap between the first and second conductive pads.

17. A method for implementing a solder jumper on a surface-mount technology (SMT) printed circuit board (PCB), the method comprising:
receiving a PCB having a plurality of conductive pads for mounting a plurality of SMT components to the PCB;
applying a first solder mask on the PCB such that a first portion of each conductive pad in a pair of adjacent conductive pads is covered by the first solder mask to expose a second portion of each conductive pad in the pair of adjacent conductive pads;
mounting an SMT component to the PCB through the pair of adjacent conductive pads in order to perform design tests; and
applying a second solder mask on the PCB after removing the SMT component, wherein the second solder mask covers the second portion of each conductive pad in the pair of adjacent conductive pads to expose the first portion of each conductive pad in the pair of adjacent conductive pads.

18. The method of claim 17, further comprising implementing a solder jumper by connecting the first exposed portions of the pair of adjacent conductive pads using solder.

19. The SMT PCB of claim 17, wherein the first portion of each conductive pad in the pair of adjacent conductive pads is adjacent an edge of the other conductive pad in the pair of adjacent conductive pads.

20. The SMT PCB of claim 17, wherein the second portion of each conductive pad in the pair of adjacent conductive pads is located on a far side of each conductive pad in relation to the other conductive pad in the pair of adjacent conductive pads.

21. The SMT PCB of claim 17, wherein the SMT component is a zero-ohm resistor, wherein the solder jumper subsequently replaces the zero-ohm resistor.

22. The SMT PCB of claim 17, wherein an edge of each conductive pad in the pair of conductive pads comprises a tab portion that extends toward the other conductive pad in the pair of conductive pads.

23. The SMT PCB of claim 17, wherein an edge of each conductive pad in the pair of conductive pads comprises a set of interlocking fingers extending toward the other conductive pad in the pair of conductive pads.

24. A surface-mount technology (SMT) printed circuit board (PCB) assembly, comprising:
at least one solder jumper comprising a pair of conductive pads and solder connecting the conductive pads, wherein a portion of each conductive pad is covered by solder mask.

25. The SMT PCB assembly of claim 24, wherein the solder jumper replaces a resistor that was mounted to the SMT PCB assembly.

26. The SMT PCB assembly of claim 25, wherein the resistor comprises a zero-ohm resistor.

27. The SMT PCB assembly of claim 24, wherein the portion of each conductive pad that is covered by the solder mask was previously exposed for performing design tests.

28. The SMT PCB assembly of claim 24, wherein the solder mask is a first solder mask, wherein the currently exposed portion of each conductive pad was previously covered by a second solder mask for performing the design tests.

29. The SMT PCB assembly of claim 24, wherein an edge of each conductive pad comprises a tab portion that extends toward the other conductive pad.

30. The SMT PCB assembly of claim 29, wherein the tab portions are offset from one another in a transverse direction.

31. The SMT PCB assembly of claim 24, wherein an edge of each conductive pad comprises a set of interlocking fingers extending toward the other conductive pad.

32. The SMT PCB assembly of claim 24, wherein the conductive pads are separated by a gap having an offset configuration, the offset configuration comprising a first portion that extends in a transverse direction, a second portion that extends in the transverse direction and that is offset from the first portion by an offset distance, and a third portion that extends perpendicularly to the first and second portions and connects adjacent ends of the first and second portions.

33. The SMT PCB assembly of claim 24, wherein the conductive pads are separated by a gap having a width between 0.003″ and 0.010″.
